(19) United States
(12) Patent Application Publication
(10) Pub. No.: US 2014/0307504 A1
(43) Pub. Date: Oct. 16, 2014

(54) DATA STORAGE DEVICE, AND FABRICATION AND CONTROL METHODS THEREOF

(71) Applicant: WINBOND ELECTRONICS CORP., Taichung City (TW)

(72) Inventors: Hsi-Hsien HUNG, Palo Alto, CA (US); Eungjoon PARK, Fremont, CA (US)

(73) Assignee: Winbond Electronics Corp., Taichung City (TW)

(21) Appl. No.: 13/861,609

(22) Filed: Apr. 12, 2013

(51) Int. Cl. G11C 16/08; H01L 27/115

(52) U.S. Cl. CPC G11C 16/08; H01L 27/11517
USPC 365/185.02; 365/185.18; 365/185.33; 438/257

(57) ABSTRACT

A data storage device and fabrication and control methods thereof are disclosed. The data storage device includes a first-first sub-block of memory cells, a second-first sub-block of memory cells, a first well switch, a second well switch and a first group of word lines. The first well switch is operative to convey a first well bias to bias the first-first sub-block of memory cells. The second well switch is operative to convey a second well bias to bias the second-first sub-block of memory cells. Further, the first-first and the second-first sub-blocks both are activated according to the first group of word lines.

### BACKGROUND OF THE INVENTION

1. Field of the Invention

The present invention relates to data storage devices and in particular, relates to FLASH memories.

2. Description of the Related Art

A FLASH memory is a general non-volatile storage device and is primarily used in data storage devices, such as memory cards, USB flash devices, solid-state drives, and so on.

A typical Flash memory comprises a plurality blocks of memory cells. All of the memory cells in a physical block are located in an isolated well and share a common well control signal. For every physical block, there is a plurality of bit lines (BL) and word lines (WL) dedicated to each physical block. A memory cell located at every intersection of the BL and WL can be addressed individually. As memory density increases, an array decoder is occupying a major portion of the total chip size. One of the approaches taken in reducing the array decoder layout size is to increase the physical block size such that the number of decoders needed may be reduced. However, few technical issues need to be solved, including: increase of sub-block erase time; cell uniformity within a physical block; and decoder layout congestion. Further, cell disturbance due to program and erase processes of a sub-block is a concern and need to be addressed in FLASH memory designs.

### BRIEF SUMMARY OF THE INVENTION

Data storage devices and fabrication and control methods thereof are disclosed.

A data storage device in accordance with an exemplary embodiment of the invention comprises a first-first sub-block of memory cells, a second-first sub-block of memory cells, a first well switch, a second well switch and a first group of word lines. The first well switch is operative to convey a first well bias to bias the first-first sub-block of memory cells. The second well switch is operative to convey a second well bias to bias the second-first sub-block of memory cells. Further, the first-first and the second-first sub-blocks both are activated according to the first group of word lines.

A fabrication method of a data storage device in accordance with an exemplary embodiment of the invention comprises the following steps: fabricating a first-first sub-block of memory cells in a first well; fabricating a second-first sub-block of memory cells in a second well different from the first well; fabricating a first well switch to convey a first well bias to bias the first-first sub-block of memory cells; fabricating a second well switch to convey a second well bias to bias the second-first sub-block of memory cells; and fabricating a first group of word lines. The first-first and the second-first sub-blocks both are activated according to the first group of word lines.

A control method of a data storage device in accordance with an exemplary embodiment of the invention comprises the following steps: controlling a first group of word lines at an erase gate level and a first well bias at an erase well level when performing an erase process on a first-first sub-group of memory cells of the data storage device, wherein, the first-first sub-block is activated according to the first group of word lines and biased by the first well bias; and, controlling a second well bias at an erase protection level when performing the erase process on the first-first sub-group of memory cells, wherein the second well bias is operative to bias a second-first sub-block of memory cells of the data storage device, and, the second-first sub-block is activated according to the first group of word lines with the first-first sub-block.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 depicts a data storage device 100 in accordance with an exemplary embodiment of the invention;

FIG. 2 is a flowchart depicting an erase operation of a sub-block;

FIG. 3 shows an erase process (S204) being performed on the sub-block Sub_Block_11 of the data storage device 100 of FIG. 1;

FIG. 4 shows a pre-program (S202) being performed on the sub-block Sub_Block_11 of the data storage device 100 of FIG. 1; and

FIG. 5 shows a post-program (S206) being performed on the sub-block Sub_Block_11 of the data storage device 100 of FIG. 1.

### DETAILED DESCRIPTION OF THE INVENTION

The following description shows several exemplary embodiments carrying out the invention. This description is made for the purpose of illustrating the general principles of the invention and should not be taken in a limiting sense. The scope of the invention is best determined by reference to the appended claims.

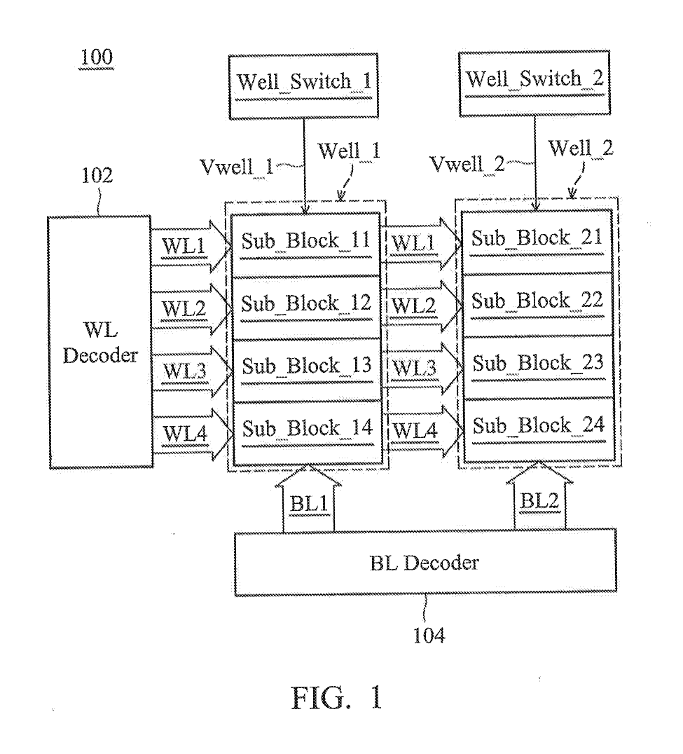

FIG. 1 depicts a data storage device 100 in accordance with an exemplary embodiment of the invention. Sub-blocks of memory cells Sub_Block_11, Sub_Block_12, Sub_Block_13 and Sub_Block_14 biased by a well bias Vwell_1 received from a well switch Well_Switch_1 are fabricated in a well Well_1. Sub-blocks of memory cells Sub_Block_21, Sub_Block_22, Sub_Block_23 and Sub_Block_24 biased by a well bias Vwell_2 received from a well switch Well_Switch_2 are fabricated in a well Well_2. The memory cells of the two different wells Well_1 and Well_2 are addressed by word lines (including four word line groups WL1, WL2, WL3 and WL4) and bit lines (including two bit line groups BL1 and BL2). A word line decoder 102 is fabricated in the data storage device 100 to control the word lines (including the four word line groups WL1, WL2, WL3 and WL4). A bit line decoder 104 is fabricated in the data storage device 100 to control the bit lines (including the two bit line groups BL1 and BL2).

Note that the FLASH memory cells locate in the two different wells Well_1 and Well_2 share the word lines. The sub-block Sub_Block_11 fabricated in the well Well_1 and the sub-block Sub_Block_21 fabricated in the well Well_2 both are activated according to a same group of word lines WL1. The sub-block Sub_Block_12 fabricated in the well Well_1 and the sub-block Sub_Block_22 fabricated in the well Well_2 both are activated according to a same group of word lines WL2. The sub-block Sub_Block_13 fabricated in the well Well_1 and the sub-block Sub_Block_23 fabricated in the well Well_2 both are activated according to a same group of word lines WL3. The sub-block Sub_Block_14 fabricated in the well Well_1 and the sub-block Sub_Block_24 fabricated in the well Well both are activated according to a same group of word lines WL4.

Further, sub-blocks of the same well may alternatively utilize a same group of bit lines. As shown, the sub-blocks Sub_Block_1, Sub_Block_12, Sub_Block_13 and Sub_Block_14 fabricated in the well Well_1 all are coupled to the bit line group BL1, and, the sub-blocks Sub_Block_{—21, Sub}_{——}Block_22, Sub_Block_23 and Sub_Block_24 fabricated in the well Well_2 all are coupled to the bit line group BL2.

Note that the number of wells sharing the same word lines is not limit to 2, and, in each well the number of sub-blocks sharing the same bit lines is not limit to 4.

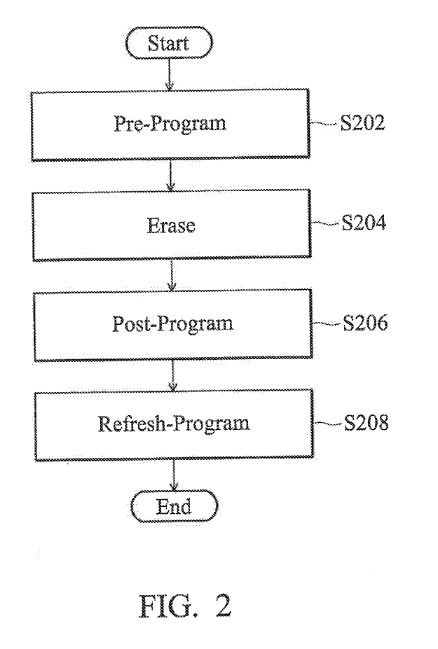

A control method of the data storage device 100 is discussed in the following paragraphs. FIG. 2 is a flowchart depicting an erase operation of a sub-block. In step S202, a pre-program process is performed on a target sub-block. An erase process is scheduled after the pre-program process and is performed in step S204. After the erase process, a post-program process is performed in step S206 to correct the over erased cells. Because sub-blocks adjacent to the target sub-block may be disturbed in the steps S202, S204 and S206, a refresh-program process is required and performed in step S208 to recover the content of the disturbed memory cells.

First, the erase process of step S204 is discussed. An erase gate level is applied on the word lines of the target sub-block when a disturbance suppression level is applied on the other word lines. The bit lines of the target sub-block are floating and the other bit lines may be floating as well. An erase well level is conveyed into the well containing the target sub-block as a well bias. As for the other well(s) having a sub-block sharing the same word lines with the target sub-block, an erase protection level is required to protect sub-blocks within the well from being disturbed by the erasing of the target sub-block.

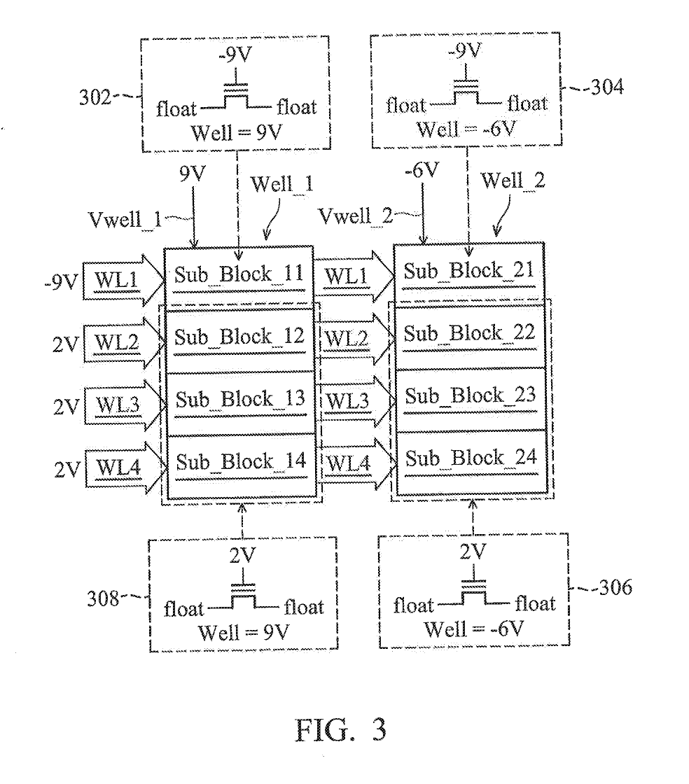

FIG. 3 shows an erase process (S204) being performed on the sub-block Sub_Block_11 of the data storage device 100 of FIG. 1. In this embodiment, the memory cells are implemented by ETOX NMOS FLASH cells (not intended to be a limitation), the erase gate level may be −9V (applied on word lines WL1), the disturbance suppression level may be 2V (applied on word lines WL2˜WL4), the erase well level may be 9V (to bias the well Well_1), and the erase protection level may be −6V (to bias the well Well_2). As shown in 302, the memory cells of the target sub-block Sub_Block_11 have a high voltage difference +18V between the substrate and the gate to enable FN tunneling for erasing. As shown in 304 and 306, the memory cells of the well Well_2 are biased by the erase protection level, −6V, and are protected from the disturbance caused by the erase process of the target sub-block Sub_Block_11. Only the sub-blocks Sub_Block_12, Sub_Block_13 and Sub_Block_14 fabricated in the same well with the target sub-block Sub_Block_11 are affected by the high voltage stress 9V at the well Well_1. As shown in 308, the disturbance suppression level 2V is operative to contend with the high well stress 9V such that disturbances on the sub-blocks Sub_Block_12, Sub_Block_13 and Sub_Block_14 due to the erase well level 9V is suppressed.

In comparison with a conventional FLASH design in which word lines are exclusive to each well, the disclosed memory uses a same word line group to control multiple wells. For a same-sized memory using a same sized address decoder, the well size of the disclosure is smaller than the conventional techniques. Thus, in comparison with the larger well size of conventional techniques, the smaller-sized well of the disclosure results in a lesser number of sub-blocks to be disturbed by the high well stress applied on the well for erasing the target sub-block therein.

The pre-program process of step S202 and the post-program process of step S206 are discussed in the following paragraphs. In a pre-program process, a pre-program enable level is utilized in the control of the word lines one WL at a time of the target sub-block and a pre-program level is utilized in the control of the bit lines section by section of the target sub-block. In a post-program process, a post-program enable level is utilized in the control of the word lines one WL at a time of the target sub-block and a post-program level is utilized in the control of the bit lines section by section of the over erased cells. In a pre-program process, a pre-program enable is utilized in a control of the word lines (one WL at a time).

To be pre-programmed, the word lines of the target sub-block may be enabled alternately by the pre-program enable level and the cells activated by the enabled word lines and within the target sub-block may be driven by the pre-program/post-program level section by section (e.g., every 4, 8 or 16 bit lines are driven together). The non-activated word lines should be biased at a program disable level. The remaining bit lines should be coupled to a ground level. Further, the well containing the target sub-block may be biased at the ground level, and the other wells may be biased at the ground level as well.

As for the post-program process, a verification test should be performed first on the target sub-block and thereby over-erased cells are picked out. The over-erased cells have to be post-programmed, by which the word lines corresponding to the over-erased cells may be enabled alternately by the post-program enable level and the over-erased cells activated by the enabled bit lines may be driven by the post-program level section by section (e.g., every 4, 8 or 16 bit lines are driven together). The non-activated word lines should be biased at a program disable level. The remaining bit lines should be coupled to a ground level. Further, the well containing the target sub-block may be biased at the ground level, and the other wells may be biased at the ground level as well.

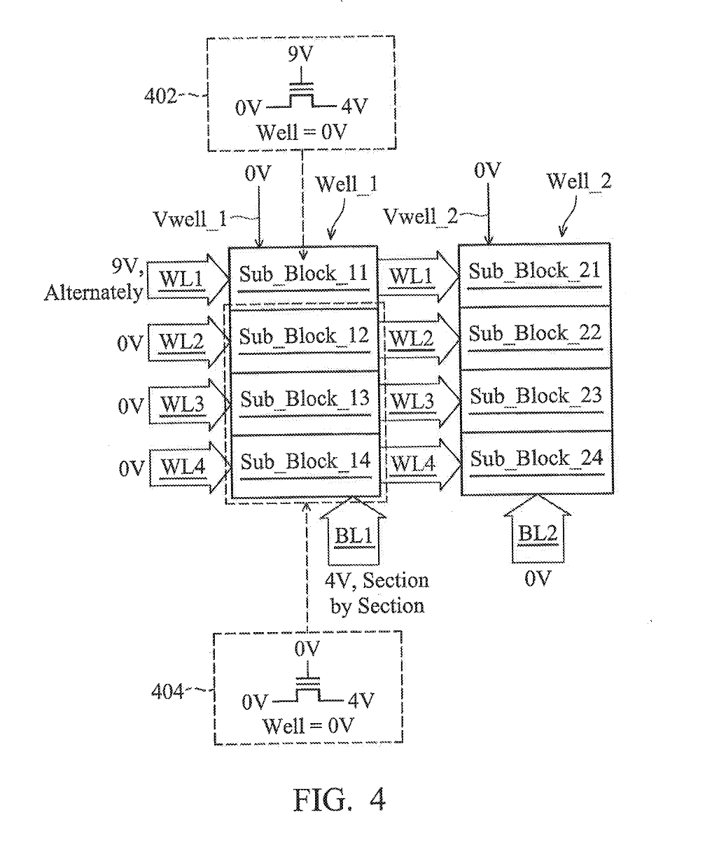

FIG. 4 shows a pre-program process (S202) being performed on the sub-block Sub_Block_11 of the data storage device 100 of FIG. 1. For ETOX NMOS FLASH cells, the pre-program enable level may be 9V (applied on word lines WL1 alternately), the program disable level may be 0V (applied on word lines WL2˜WL4 and the non-activated word lines of WL1), and the pre-program level may be 4V (applied on the bit lines BL1 section by section). As shown in 402, to be pre-programmed, a memory cell is activated by the WL pre-program enable level (9V) to be programmed by the BL pre-program level (4V). Note that the sub-blocks Sub_Blocks_12, Sub_Block_13 and Sub_Block_14 disturbed by the erase operation of step S204 may also be disturbed by the pre-program and post-program BL enable level (4V) (as shown in 404).

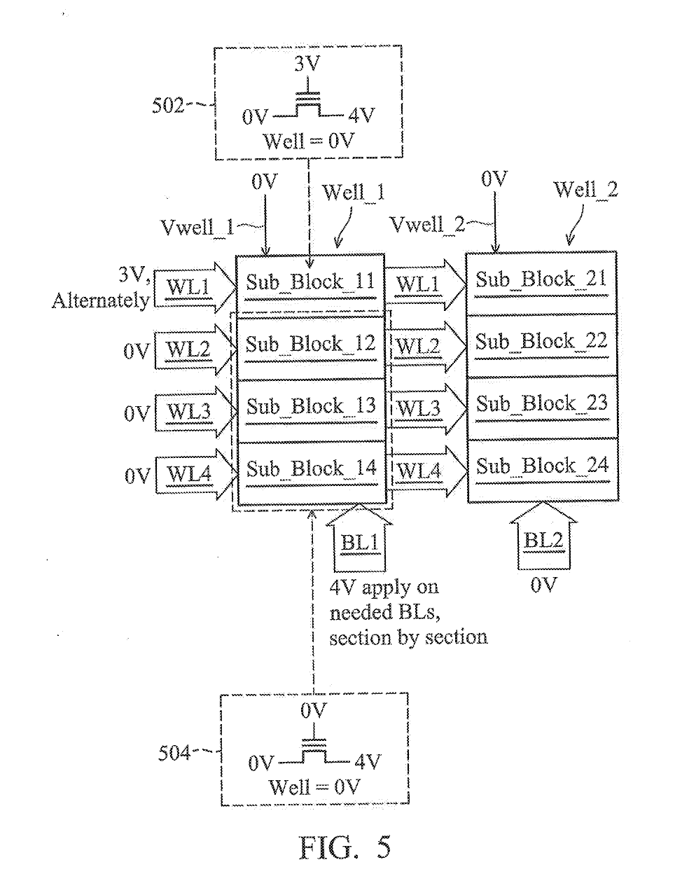

FIG. 5 shows a post-program process (S206) being performed on over-erased cells of the sub-block Sub_Block_11 of the data storage device 100 of FIG. 1. For ETOX NMOS FLASH cells, the post-program WL enable level may be 3V (alternately applied on word lines of the over-erased cells), the program disable level may be 0V (applied on word lines WL2˜WL4 and the non-activated word lines of WL1), and the pre-program/post-program level may be 4V (applied on the bit lines of the over-erased cells section by section). As shown in 502, an over-erased memory cell is activated by the post-program enable level (3V) to be programmed by the pre-program/post-program level (4V). Note that the sub-blocks Sub_Blocks_12, Sub_Block_13 and Sub_Block_14 disturbed by the erase operation of step S204 may also be disturbed by the pre-program/post-program level (4V) (as shown in 504).

Considering the disturbances depicted in 308 of FIG. 3, 404 of FIGS. 4 and 504 of FIG. 5, the refresh-program process of step S208 of FIG. 2 is required to recover the memory cells of the sub-blocks Sub_Block_12, Sub_Block_13 and Sub_Block_14 fabricated in the same well Well_1 with the target sub-block Sub_Block_11. As discussed above, for a same-sized memory using a same sized address decoder, each well of the disclosure includes lesser sub-blocks in comparison with a conventional memory design. Thus, the number of sub-blocks disturbed during the steps S202-S206 is reduced according to the disclosure. The refresh time spent for recovery of the disturbed sub-blocks is shorter in comparison with conventional techniques.

Further, a fabrication method of a data storage device in accordance with an exemplary embodiment of the invention is disclosed and discussed with respect to FIG. 1. The fabrication method includes the following steps: fabricating a first-first sub-block of memory cells Sub_Block_11 in a first well fabricating a second-first sub-block of memory cells Sub_block_21 in a second well Well_2 different from the first well Well_1; fabricating a first well switch Well_Switch_1 to convey a first well bias Vwell_1 to bias the first-first sub-block of memory cells Sub_Block_11; fabricating a second well switch Well_Switch_2 to convey a second well bias Vwell_2 to bias the second-first sub-block of memory cells Sub_block_21; and fabricating a first group of word lines WL1. The first-first and the second-first sub-blocks Sub_block_11 and Sub_block_21 both are activated according to the first group of word lines WL1. According to the fabrication method, sub-blocks of different wells share a same group of word lines. For a same-sized memory using a same sized address decoder, each well of the disclosure includes lesser sub-blocks in comparison with a conventional well. The number of sub-blocks disturbed during the steps S202-S206 of FIG. 2 is reduced according to the disclosure.

The fabrication method may further include: fabricating a first-second sub-block of memory cells Sub_block_12 in the first well Well_1, wherein the first-second sub-block Sub_block_12 is biased by the first well bias Vwell_1 with the first-first sub-block Sub_Block_11; fabricating a second-second sub-block of memory cells Sub_block_22 in the second well Well_2, wherein the second-second sub-block Sub_block_22 is biased by the second well bias Vwell_2 with the second-first sub-block Sub_block_{—}21; fabricating a second group of word lines WL2, wherein the first-second and the second-second sub-blocks Sub_block_12 and Sub_block_22 both are activated according to the second group of word lines WL2; fabricating a first group of bit lines BL1 coupled to the first-first and the first-second sub-blocks Sub_block_11 and Sub_block_12 both; and fabricating a second group of bit lines BL2 coupled to the second-first and the second-second sub-blocks Sub_Block_21 and Sub_block_22 both. A complete memory array may be fabricated according to the basic array formed by the sub-blocks Sub_Block_11, Sub_Block_12, Sub_Block_21 and Sub_Block_22.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A data storage device, comprising
a first-first sub-block of memory cells and a first well switch conveying a first well bias to bias the first-first sub-block of memory cells;
a second-first sub-block of memory cells and a second well switch conveying a second well bias to bias the second-first sub-block of memory cells, and
a first group of word lines,
wherein the first-first and the second-first sub-blocks both are activated according to the first group of word lines.

2. The data storage device as claimed in claim 1, further comprising:
a word line decoder, controlling the first group of word lines;
wherein, during an erase process of the first-first sub-block of memory cells, the word line decoder controls the first group of word lines at an erase gate level, and the first well bias and the second well bias are controlled at an erase well level and an erase protection level, respectively, such that the second-first sub-block is protected from disturbance caused by the erase process of the first-first sub-block.

3. The data storage device as claimed in claim 2, further comprising:
a first-second sub-block of memory cells and a second-second sub-block of memory cells; and
a second group of word lines,
wherein:
the first-second and the second-second sub-blocks both are activated according to the second group of word lines;
the first-second sub-block is biased by the first well bias with the first-first sub-block; and
the second-second sub-block is biased by the second well bias with the second-first sub-block.

4. The data storage device as claimed in claim 3, wherein:
the word line decoder further controls the second group of word lines; and
during the erase process of the first-first sub-block of memory cells, the word line decoder further controls the second group of word lines at a disturbance suppression level to suppress a disturbance on the first-second sub-block due to the erase well level of the first well bias.

5. The data storage device as claimed in claim 4, further comprising:
a first group of bit lines; and
a second group of bit lines,
wherein:
the first-first and the first-second sub-blocks both are coupled to the first group of bit lines; and
the second-first and the second-second sub-blocks both are coupled to the second group of bit lines.

6. The data storage device as claimed in claim 5, further comprising:
a bit line decoder, controlling the first and second groups of bit lines,
wherein:
in a pre-program process before the erase process of the first-first stab-block, the word line decoder activates the first group of word lines alternately by a pre-program WL enable level and controls non-activated word lines at a program WL disable level, and, the bit line decoder controls the first group of bit lines at a pre-program BL enable level section by section, different from a ground level applied on the remaining bit lines; and
in a post-program process after the erase process of the first-first sub-block, the word line decoder activates the word lines corresponding to over-erased memory cells alternately by a post-program WL enable level and controls non-activated word lines at the program WL disable level, and, the bit line decoder controls the bit lines corresponding to the over-erased memory cells at the post-program BL enable level section by section, different from the ground level applied on the remaining bit lines.

7. The data storage device as claimed in claim 1, wherein the first-first sub-block is fabricated in a first well and second-first sub-block is fabricated in a second well separated from the first well.

8. The data storage device as claimed in claim 1 is implemented as a FLASH memory.

9. A fabrication method of a data storage device, comprising:
fabricating a first-first sub-block of memory cells in a first well;
fabricating a second-first sub-block of memory cells in a second well separated from the first well;
fabricating a first well switch to convey a first well bias to bias the first-first sub-block of memory cells;
fabricating a second well switch to convey a second well bias to bias the second-first sub-block of memory cells; and
fabricating a first group of word lines,
wherein the first-first and the second-first sub-blocks both are activated according to the first group of word lines.

10. The fabrication method as claimed in claim 9, further comprising:
fabricating a first-second sub-block of memory cells in the first well, wherein the first-second sub-block is biased by the first well bias with the first-first sub-block;
fabricating a second-second sub-block of memory cells in the second well, wherein the second-second sub-block is biased by the second well bias with the second-first sub-block; and
fabricating a second group of word lines, wherein the first-second and the second-second sub-blocks both are activated according to the second group of word lines.

11. The fabrication method as claimed in claim 10, further comprising:
fabricating a first group of bit lines coupled to the first-first and the first-second sub-blocks both; and
fabricating a second group of bit lines coupled to the second-first and the second-second sub-blocks both.

12. A control method of a data storage device, comprising:
controlling a first group of word lines at an erase gate level and a first well bias at an erase well level when performing an erase process on a first-first sub-group of memory cells of the data storage device, wherein, the first-first sub-block is activated according to the first group of word lines and biased by the first well bias; and
controlling a second well bias at an erase protection level when performing the erase process on the first-first sub-group of memory cells, wherein the second well bias is operative to bias a second-first sub-block of memory cells of the data storage device, and, the second-first sub-block is activated according to the first group of word lines with the first-first sub-block.

13. The control method as claimed in claim 1 further comprising:
controlling a second group of word lines at a disturbance suppression level when performing the erase process on the first-first sub-group of memory cells,
wherein:
the second group of word lines are operative to activate a first-second sub-block of memory cells and a second-second sub-block of memory cells of the data storage device;
the first-second sub-block is biased by the first well bias with the first-first sub-block;
the second-second sub-block is biased by the second well bias with the second -first sub-block; and
the disturbance suppression level at the second group of word lines suppress a disturbance on the first-second sub-block due to the erase well level of the first well bias.

14. The control method as claimed in claim 13, further comprising:
in a pre-program process before the erase process of the first-first sub-block, activating the first group of word lines alternately by a pre-program WL enable level, controlling non-activated word lines at a program WL disable level, and controlling a first group of bit lines at a pre-program BL enable level section by section, different from a ground level applied on the remaining bit lines; and
in a post-program process after the erase process of the first-first sub-block, activating the word lines corresponding to over-erased memory cells alternately by a post-program WL enable level, controlling non-activated word lines at the program WL disable level, and controlling the bit lines corresponding to the over-erased memory cells at the post-program BL enable level section by section, different from the ground level applied on the remaining bit lines,
wherein:
the first-first and the first-second sub-blocks both are coupled to the first group of bit lines; and
the second-first and the second-second sub-blocks both are coupled to a second group of bit lines.
